(19) United States
(12) Patent Application Publication
(10) Pub. No.: US 2008/0203487 A1
(43) Pub. Date: Aug. 28, 2008

(54) FIELD EFFECT TRANSISTOR HAVING AN INTERLAYER DIELECTRIC MATERIAL HAVING INCREASED INTRINSIC STRESS

(76) Inventors: Joerg Hohage, Dresden (DE); Michael Finken, Dresden (DE); Christof Streck, Coswig (DE); Ralf Richter, Dresden (DE)

Correspondence Address: WILLIAMS, MORGAN & AMERSON, 10333 RICHMOND, SUITE 1100, HOUSTON, TX, 77042, US

(21) Appl. No.: 11/873,547

(22) Filed: Oct. 17, 2007

(30) Foreign Application Priority Data
Feb. 28, 2007 (DE) 10 2007 009 914.4

(51) Int. Cl. H01L 21/469; H01L 29/78

(52) U.S. Cl. 257/369; 438/783; 257/E29.255; 257/E21.487

(57) ABSTRACT

By providing a highly stressed interlayer dielectric material, the performance of at least one type of transistor may be increased due to an enhanced strain-inducing mechanism. For instance, by providing a highly compressive silicon dioxide of approximately 400 Mega Pascal and more as an interlayer dielectric material, the drive current of the P-channel transistors may be increased by 2% and more while not unduly affecting the performance of the N-channel transistors.

### BACKGROUND OF THE INVENTION

1. Field of the Invention

Generally, the present disclosure relates to the field of integrated circuits, and, more particularly, to the manufacture of P-channel field effect transistors having a strained channel region caused by a stressed contact etch stop layer.

2. Description of the Related Art

Integrated circuits typically comprise a large number of circuit elements on a given chip area according to a specified circuit layout, wherein, in complex circuits, the field effect transistor represents one important device component. Generally, a plurality of process technologies are currently practiced, wherein, for complex circuitry based on field effect transistors, such as microprocessors, storage chips and the like, MOS technology is currently one of the most promising approaches due to the superior characteristics in view of operating speed and/or power consumption and/or cost efficiency. During the fabrication of complex integrated circuits using MOS technology, millions of transistors, in CMOS technology, complementary transistors, i.e., N-channel transistors and P-channel transistors, are formed on a substrate including a crystalline semiconductor layer. A field effect transistor, irrespective of whether an N-channel transistor or a P-channel transistor is considered, comprises so-called PN junctions that are formed by an interface of highly doped drain and source regions with an inversely or weakly doped channel region disposed between the drain region and the source region.

The conductivity of the channel region, i.e., the drive current capability of the conductive channel, is controlled by a gate electrode formed above the channel region and separated therefrom by a thin insulating layer. The conductivity of the channel region, upon formation of a conductive channel due to the application of an appropriate control voltage to the gate electrode, depends on the dopant concentration, the mobility of the majority charge carriers, and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the conductivity of the channel region substantially determines the performance of the MOS transistors. Thus, the reduction of the channel length, and associated therewith the reduction of the channel resistivity, may be dominant design criteria for accomplishing an increase in the operating speed of integrated circuits.

The shrinkage of the transistor dimensions, however, involves a plurality of issues associated therewith that have to be addressed so as to not unduly offset the advantages obtained by steadily decreasing the channel length of MOS transistors. One problem in this respect is the development of enhanced photolithography and etch strategies so as to reliably and reproducibly create circuit elements of critical dimensions, such as the gate electrode of the transistors, for a new device generation. Moreover, highly sophisticated dopant profiles, in the vertical direction as well as in the lateral direction, are required in the drain and source regions to provide low sheet and contact resistivity in combination with a desired channel controllability.

Since the continuous size reduction of the critical dimensions, i.e., the gate length of the transistors, necessitates the adaptation and possibly the new development of process techniques concerning the above-identified complex process steps, it has been proposed to enhance device performance of the transistor elements not only by reducing the transistor dimensions but also by increasing the charge carrier mobility in the channel region for a given channel length. One efficient approach is the modification of the lattice structure in the channel region, for instance by creating tensile or compressive strain therein, which results in a modified mobility for electrons and holes, respectively. For example, creating tensile strain in the channel region of a silicon layer having a standard crystallographic configuration may increase the mobility of electrons, which in turn may directly translate into a corresponding increase in the conductivity for N-type transistors. On the other hand, compressive strain in the channel region may increase the mobility of holes, thereby providing the potential for enhancing the performance of P-type transistors. Consequently, it has been proposed to introduce, for instance, a silicon/germanium layer or a silicon/carbon layer in or near the channel region to create tensile or compressive stress. Although the transistor performance may be considerably enhanced by the introduction of strain-creating layers in or below the channel region, significant efforts have to be made to implement the formation of corresponding strain-inducing layers into the conventional and well-approved CMOS technique. For instance, additional epitaxial growth techniques have to be developed and implemented into the process flow to form the germanium- or carbon-containing stress layers at appropriate locations in or below the channel region. Hence, process complexity is significantly increased, thereby also increasing production costs and the potential for a reduction in production yield.

Therefore, a technique is frequently used that enables the creation of desired stress conditions within the channel region of different transistor elements by modifying the stress characteristics of a contact etch stop layer that is formed above the basic transistor structure in order to form contact openings to the gate and drain and source terminals in an interlayer dielectric material. The effective control of mechanical stress in the channel region, i.e., an effective stress engineering, may be accomplished by individually adjusting the internal stress in the contact etch stop layers located above the respective transistor elements so as to position a contact etch stop layer having an internal compressive stress above a P-channel transistor while positioning a contact etch stop layer having an internal tensile strain above an N-channel transistor, thereby creating compressive and tensile strain, respectively, in the respective channel regions.

Typically, the contact etch stop layer is formed by plasma enhanced chemical vapor deposition (PECVD) processes above the transistor, i.e., above the gate structure and the drain and source regions, wherein, for instance, silicon nitride may be used due to its high etch selectivity with respect to silicon dioxide, which is a well-established interlayer dielectric material. Furthermore, PECVD silicon nitride may be deposited with a high intrinsic stress, for example, up to 2 Giga Pascal (GPa) or significantly higher of tensile or compressive stress, wherein the type and the magnitude of the intrinsic stress may be efficiently adjusted by selecting appropriate deposition parameters. For example, ion bombardment, deposition pressure, substrate temperature, gas components and the like represent respective parameters that may be used for obtaining the desired intrinsic stress. Since the contact etch stop layer is positioned close to the transistor, the intrinsic stress may be efficiently transferred into the channel region, thereby significantly improving the performance thereof. Moreover, for advanced applications, the strain-inducing contact etch stop layer may be efficiently combined with other strain-inducing mechanisms, such as strained or relaxed semiconductor materials that are incorporated at appropriate transistor areas in order to also create a desired strain in the channel region. Consequently, the stressed contact etch stop layer is a well-established design feature for advanced semiconductor devices. The amount of the intrinsic stress may, however, be restricted due to process-specific limitations. Therefore, the thickness of the respective etch stop layers is typically increased, which also results in an increase of the respective strain in the channel region. For example, the effective compressive force and thus the corresponding strain in P-channel transistors may be efficiently raised by increasing the thickness of the contact etch stop layer. The layer thickness may, however, have to be adapted to the requirements of the subsequent contact etch step, which typically demands a moderately low thickness of several hundred nanometers and less, in particular for sophisticated devices comprising dense patterns, at which the conformal behavior of the etch stop layer may no longer be maintained. Thus, although the provision of a highly stressed etch stop material above P-channel transistors represents an efficient approach for enhancing drive current and switching speed, the achievable gain in performance may be restricted by the deposition characteristics for and the thickness of the contact etch stop layer.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the subject matter disclosed herein is directed to methods and devices for obtaining enhanced strain-inducing mechanisms in order to enhance charge carrier mobility in respective channel regions of transistors on the basis of stressed dielectric materials formed above the transistor elements. For this purpose, the interlayer dielectric material provided above the respective transistor elements and separating the transistors from the first metallization level may be used for enhanced stressed engineering so as to at least significantly increase the performance of one type of transistors. That is, additionally or alternatively to respective contact etch stop layers of high intrinsic stress, the interlayer dielectric material may be provided with an appropriate intrinsic stress level in order to create a respective strain in the channel region of at least one transistor type. Thus, by “incorporating” the actual interlayer dielectric material into the stress engineering mechanism, respective limitations of conventional stress engineering approaches may be overcome or at least significantly reduced, since the deposition of the respective contact etch stop layers may, for instance, be preferentially performed on the basis of pattern-specific constraints rather than in view of intrinsic stress considerations. Consequently, the layer thickness and the intrinsic stress levels of the contact etch stop layers may be selected to provide enhanced performance of the manufacturing sequence under consideration, while, at least for one type of transistor, an efficient strain-inducing mechanism may be obtained on the basis of the subsequently formed interlayer dielectric material.

One illustrative method disclosed herein comprises forming a first etch stop layer above a P-channel transistor and forming an interlayer dielectric material above the first etch stop layer, wherein the interlayer dielectric material comprises at least a layer portion having a compressive stress of approximately 400 MPa (Mega Pascal) or higher. Furthermore, a contact opening is formed in the interlayer dielectric material wherein the first etch stop layer is used as an etch stop.

Another illustrative method disclosed herein comprises forming a first etch stop layer above a first transistor and forming a second etch layer above a second transistor, wherein the first and second etch stop layers differ from each other in the amount of intrinsic stress and/or the type of intrinsic stress. Furthermore, an interlayer dielectric material is formed above the first and second etch stop layers, wherein the interlayer dielectric layer comprises a portion located above the first transistor and having an intrinsic stress level that is selected such that a strain level in a channel region of the first transistor is adjusted by the intrinsic stress level.

One illustrative semiconductor device disclosed herein comprises a first transistor and a first etch stop layer formed above the first transistor. The semiconductor device further comprises a first interlayer dielectric material formed on the first etch stop layer and having an intrinsic stress level of approximately 400 Mega Pascal or higher.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1c schematically illustrate cross-sectional views of transistor elements embedded in an interlayer dielectric material having a high intrinsic stress level during various manufacturing stages according to illustrative embodiments;

FIGS. 1d-1f schematically illustrate cross-sectional views of transistors of different conductivity type during the formation of an interlayer dielectric material having a high intrinsic stress level with a corresponding dielectric buffer material for reducing the effect of the interlayer dielectric material above one type of transistor according to further illustrative embodiments; and

FIG. 1g schematically illustrates a cross-sectional view of a semiconductor device including two different types of transistors during the formation of etch stop layers of different intrinsic stress levels according to an enhanced process flow, prior to forming a highly stressed interlayer dielectric material, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the subject matter disclosed herein relates to a technique for providing a strain-inducing mechanism on the basis of stressed dielectric materials formed above respective transistor elements wherein the efficiency of at least a compressive stress source may be effectively enhanced by appropriately forming an interlayer dielectric material with a high intrinsic stress level so as to adjust the respective strain in the transistor elements enclosed by the highly stressed interlayer dielectric material. The provision of the highly stressed interlayer dielectric material may be efficiently combined with an appropriate stress-inducing mechanism obtained on the basis of highly stressed etch stop layers which are typically provided close to the respective transistor elements in order to control a subsequent anisotropic etch process for forming respective contact openings in the interlayer dielectric material. In some aspects, well-established deposition techniques such as plasma enhanced chemical vapor deposition (PECVD) processes may be used for forming a highly stressed interlayer dielectric material on the basis of silicon dioxide in order to obtain a high compressive stress which may result in a corresponding gain in performance of P-channel transistors while avoiding, or at least significantly reducing, any disadvantages that may be encountered in conventional strategies attempting to enhance the stress-inducing mechanism by increasing the stress level and/or the thickness of the respective silicon nitride based contact etch stop layers.

For instance, for standard crystallographic conditions, i.e., for a silicon-based semiconductor material having a (100) surface orientation with respective channel regions oriented along the (110) direction, the mobility of holes may be significantly enhanced by providing a compressive strain along the channel length direction which may be accomplished by respective layers positioned close to the transistor element and having a high compressive stress. Similarly, for the same crystallographic conditions, a respective high tensile stress may induce a respective strain in N-channel transistors for enhancing the electron mobility. For this purpose, typically the contact etch stop layer, which is usually formed from silicon nitride, is provided with high compressive stress above the P-channel transistor and with high tensile stress above the N-channel transistor in order to enhance transistor performance. Thereafter, in conventional strategies, the interlayer dielectric material, typically comprised of silicon dioxide, may be deposited with moderately low compressive stress, i.e., with a stress level of approximately 100 Mega Pascal (MPa) or significantly less or with a low tensile stress, depending on the respective deposition parameters. However, a respective low intrinsic stress level may not efficiently act on the corresponding channel regions so that the finally obtained gain in performance is substantially determined by the stressed etch stop layers or any other stress-inducing sources, such as embedded strained or relaxed semiconductor compounds and the like.

According to embodiments disclosed herein, the efficiency of stressed contact etch stop layers may be significantly enhanced by also providing at least significant portions of the interlayer dielectric material with high intrinsic stress levels wherein, at least for one transistor type, a significant increase in performance gain may be accomplished without unduly negatively affecting the other type of transistors, even if the corresponding highly stressed interlayer dielectric material may be directly formed on both types of stressed contact etch stop layers. For instance, a high compressive stress with an intrinsic stress level of approximately 400 Mega Pascal, or even higher, may result in a significant strain in a P-channel transistor, wherein the high intrinsic tensile stress of the contact etch stop layer formed above the N-channel transistor may efficiently “shield” the compressive stress, thereby reducing the corresponding performance of the N-channel transistor within a tolerable range. In some aspects, the intrinsic stress level of the respective contact etch stop layer may be less critical and may therefore be selected in view of enhancing the process flow for forming the contact etch stop layer and subsequent device features, since the respective desired strain in the channel region may be substantially determined by the stress-inducing mechanism provided by the highly stressed interlayer dielectric material. Thus, the overall process efficiency may be enhanced, for instance, with respect to complexity, throughput and the like, while nevertheless obtaining an efficient strain-inducing mechanism.

In some illustrative embodiments, at least the performance of P-channel transistors may be enhanced by providing a silicon dioxide based interlayer dielectric material that may be formed, contrary to conventional approaches, with a high intrinsic compressive stress on the basis of PECVD techniques, thereby maintaining a high degree of compatibility with conventional strategies. Silicon dioxide formed by PECVD may have superior characteristics with respect to the deposition behavior and the material integrity during the further processing of semiconductor devices, wherein respective process parameters, such as ion bombardment during the deposition, pressure, temperature and the like, may be selected so as to deposit the silicon dioxide material with high compressive stress. In addition, the respective mechanical and chemical characteristics of the highly stressed silicon dioxide material may nevertheless comply with the requirements demanded by the further processing, for instance, with respect to chemical mechanical polishing (CMP) for planarizing the resulting surface topography and the subsequent anisotropic etch process for forming respective contact openings in the interlayer dielectric material. For instance, silicon dioxide may be formed on the basis of PECVD using TEOS (tetra-ethyl-ortho-silicate) and oxygen, thereby forming a silicon dioxide having relatively high mechanical stability, at temperatures below 600° C. at high deposition rates, thereby contributing to a high production throughput. The corresponding silicon dioxide material, in addition to a high intrinsic stress level and a high mechanical stability, exhibits a high resistance against the incorporation of moisture, which may be advantageous in view of the further processing of the device, for instance, with respect to performing the CMP process and the like. In other cases, silane may also be used as an efficient precursor material when a silicon dioxide based interlayer dielectric material with high intrinsic stress is to be formed. Also, in this case, the respective process parameters identified above may be appropriately adjusted in order to obtain the desired high intrinsic stress level of, for instance, 400 Mega Pascal and higher, wherein even values of 1 Giga Pascal and more may be used when considered appropriate for the semiconductor device under consideration.

In still other illustrative aspects of the subject matter disclosed herein, any negative impact of a highly stressed interlayer dielectric material, for instance, based on silicon dioxide, may be efficiently reduced by locally providing a dielectric buffer material designed to reduce the stress acting on the underlying transistor element. For instance, in the above-described situation, the interlayer dielectric material may be provided as a silicon dioxide based material having high compressive stress, which may be advantageous in view of enhancing performance of P-channel transistors. On the other hand, an N-channel transistor may have formed thereon an etch stop layer of high intrinsic tensile stress, the effect of which may at least be partially compensated for by the respective compressively stressed interlayer dielectric material. In this case, an appropriate buffer layer may be locally provided which may have a similar material composition to provide a high degree of compatibility during the subsequent etch process while nevertheless reduce the effect of the overlying interlayer dielectric material or even provide an increased overall tensile stress in the N-channel transistor. For this purpose, a silicon dioxide material may be formed on the basis of a thermal chemical vapor deposition (CVD) process using TEOS as a precursor material, thereby providing a deposition process having excellent gap fill capabilities wherein a high degree of conformality, or if required a substantially “flow-like” fill behavior, may be achieved, depending on the process parameters selected. The respective thermal deposition process may be performed at significantly higher pressures compared to the plasma enhanced deposition technique, for instance, in the range of 200-760 Torr, and therefore the process is frequently denoted as sub-atmospheric chemical vapor deposition (SACVD). The silicon dioxide material obtained by this process may have significantly different characteristics, in particular with respect to its internal stress level, since typically the silicon dioxide material may be deposited so as to exhibit a moderately high tensile stress. Tensile silicon dioxide could also be provided by means of a PECVD-TEOS process with optimized plasma conditions. Tensile silicon dioxide material may readily absorb water, thereby resulting in an alteration of the intrinsic stress, which may even lead to a significant compressive stress upon enhanced absorption of moisture. Consequently, by providing a buffer or etch stop comprised of a silicon dioxide material of increased tensile stress locally above N-channel transistors prior to forming the actual highly compressive interlayer dielectric material, the stress characteristics of the buffer layer (i.e., tensile silicon dioxide) may be maintained due to the encapsulation by the mechanical stable compressive PECVD interlayer dielectric material so that the corresponding N-channel transistor may be shielded by the buffer or etch stop layer or a corresponding tensile strain may even be enhanced. Consequently, the characteristics of respective etch stop layers, such as intrinsic stress, layer thickness and thus degree of conformality, may be selected in view of requirements demanded by the device geometry, while the finally desired strain in the respective channel regions may be adjusted on the basis of the intrinsic stress level of the interlayer dielectric material.

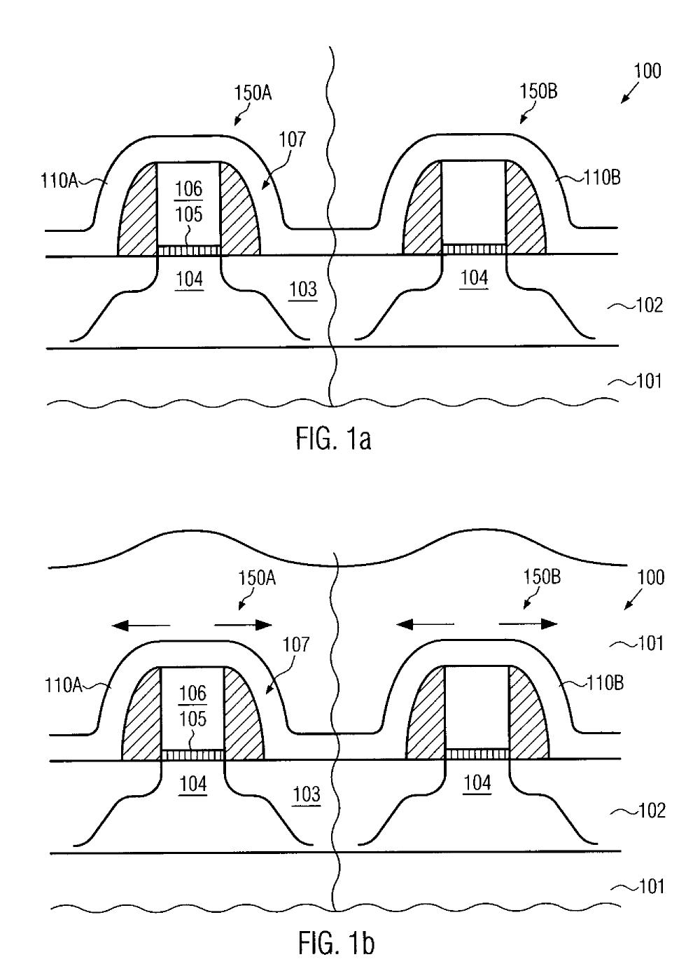

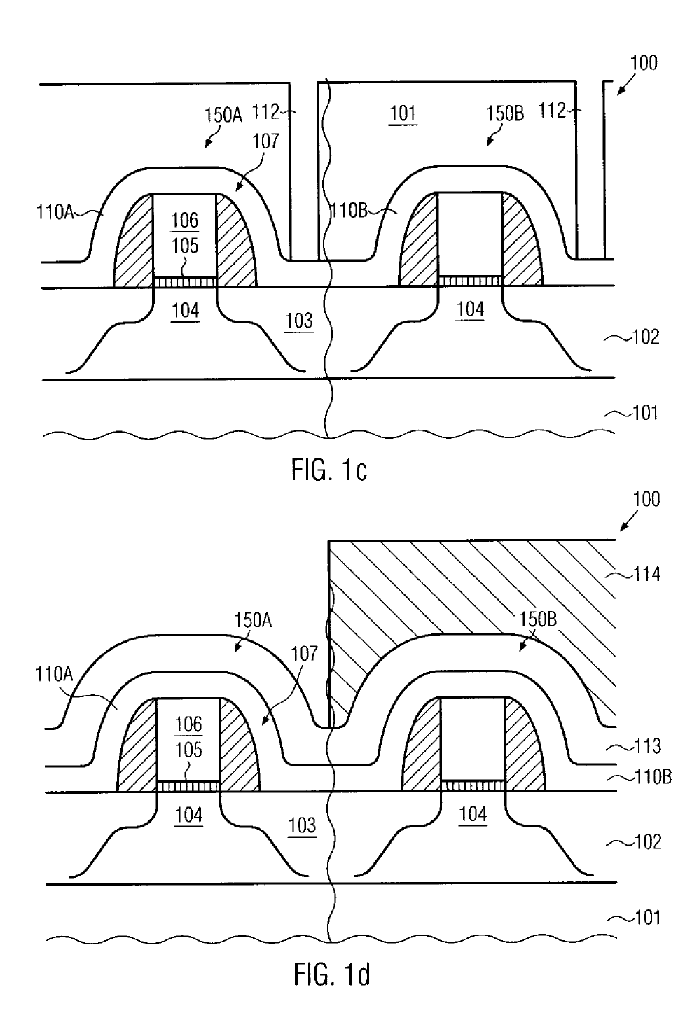

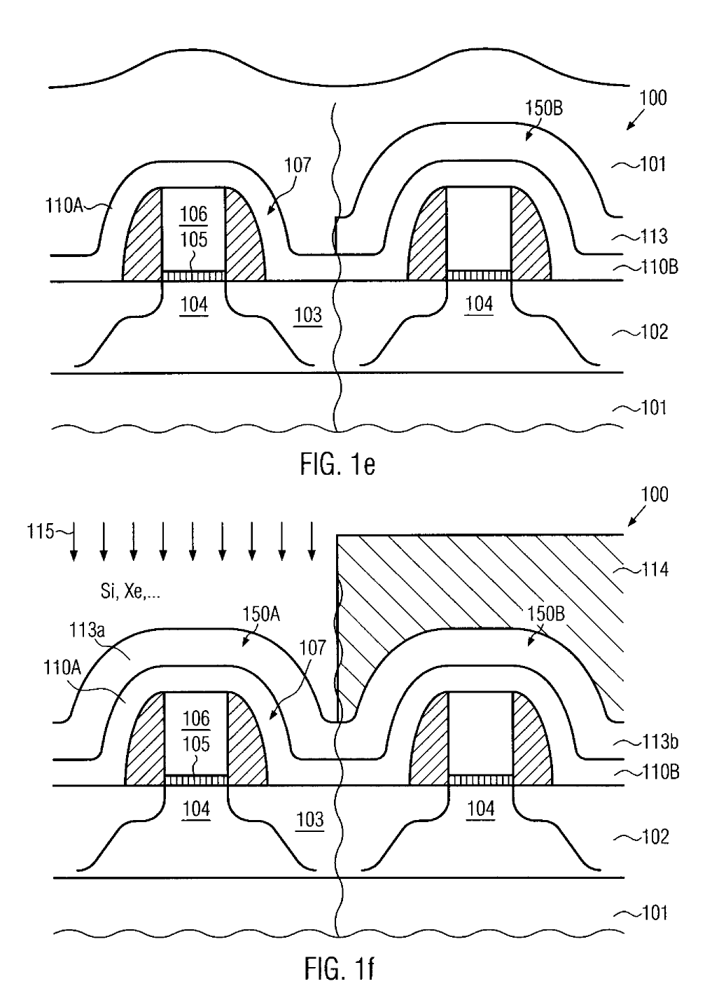

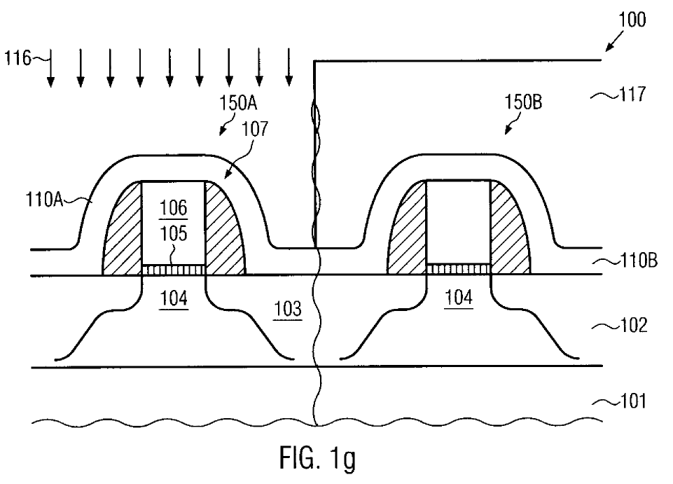

FIG. 1a schematically illustrates a cross-sectional view of a semiconductor device 100, comprising a first transistor 150A and a second transistor 150B, which may differ in their configuration so as to require different types of strain in the respective channel regions for enhancing the performance thereof, i.e., for increasing the drive current and switching speed. For instance, the transistor 150A may represent a P-channel transistor which may require a respective compressive strain for a specified crystallographic orientation, as previously explained, while the transistor 150B may represent an N-channel transistor requiring a tensile strain in its channel region. It should be appreciated, however, that other transistor configurations may be contemplated by the embodiments described herein when a different type of strain-inducing mechanism may be advantageous with respect to the overall device performance. The transistors 150A, 150B may differ in their configuration with respect to dopant profiles, type of dopant, species used, transistor dimensions and the like. For convenience, such differences are not shown and described herein. The semiconductor device 100 may comprise a substrate 101 which may represent any appropriate carrier material such as a semiconductor bulk substrate, a silicon-on-insulator (SOI) type substrate and the like. For example, the substrate 101 may represent a bulk silicon substrate having formed thereon an appropriate semiconductor layer 102, such as a silicon-based material, the characteristics of which may be locally adjusted with respect to its charge carrier mobility by inducing a corresponding strain in specified portions of the semiconductor layer 102. In other cases, the substrate 101 may have formed thereon a buried insulating layer (not shown) on which may be formed the semiconductor layer 102 so as to provide an SOI architecture. Furthermore, the semiconductor layer 102 may comprise respective isolation structures (not shown), such as shallow trench isolations and the like, in order to separate respective active regions such as the first and second transistors 150A, 150B.

Furthermore, each of the transistors 150A, 150B may comprise a gate electrode 106 formed on a respective gate insulation layer 105 separating the gate electrode 106 from a respective channel region 104. Moreover, respective drain and source regions 103 are formed adjacent to the corresponding channel region 104. Depending on the process strategy and the device requirements, a sidewall spacer structure 107 may be formed on sidewalls of the gate electrodes 106, wherein it should be appreciated that the spacer structures 107 may be different for the respective transistors, depending on process and device requirements. The spacer structure 107 may include a plurality of individual spacer elements which may be separated by respective liner materials (not shown) in order to provide respective controllability of etch processes during the patterning of the spacer structure 107. In other cases, the spacer structure 107 may be reduced to a certain degree in order to reduce the width dimensions and/or the height dimensions thereof, depending on the process strategy, thereby also enhancing the stress transfer mechanism. Consequently, unless explicitly set forth in the specification and/or the appended claims, the spacer structure 107 may have any configuration as required for the transistors 150A, 150B. Furthermore, one or both of the transistors 150A, 150B may comprise additional strain-inducing sources, such as strained semiconductor material and the like. For example, the first transistor 150A, when representing a P-channel transistor, may have incorporated therein a strained silicon/germanium material, thereby creating additional strain in the respective channel region 104. Similarly, an appropriate strain-inducing mechanism may be provided in the transistor 150B while, in other illustrative embodiments, the respective strain in the channel regions 104 may be substantially determined on the basis of dielectric material to be formed above the first and second transistors 150A, 150B.

In the manufacturing stage shown, the device 100 may comprise a first dielectric layer 110A, which may represent a contact etch stop layer, wherein, in some illustrative embodiments, the first layer 110A may also act as a stress-inducing layer for enhancing the strain in the channel region 104 of the first transistor 150A. For example, the layer 110A may comprise any appropriate material having a high etch selectivity to an interlayer dielectric material still to be formed, wherein a respective thickness of the layer 110A, as well as the type and amount of intrinsic stress, may be selected so as to obtain a desired degree of conformality, the desired etch stop characteristics and a desired type and amount of intrinsic stress, depending on the subsequent process strategy. In some illustrative embodiments, the intrinsic stress level of the first layer 110A may be selected to enhance the performance of the transistor 150A and may thus have the same type of intrinsic stress as an interlayer dielectric material to be formed above the first transistor 150A. For example, the layer 110A may have a high compressive stress in the range of 1 GPa or significantly higher, such as 2 GPa and more, depending on the device requirements. For example, the first layer 110A may be comprised of silicon nitride which may be directly formed on the respective transistor areas, i.e., the drain and source regions 103 and the gate electrode 106, or on respective metal silicide regions (not shown), while, in other illustrative embodiments, an additional liner material may be provided when respective patterning regimes for providing the etch stop layers of different intrinsic stress above the first and second transistors 150A, 150B are required. In other illustrative embodiments, the layer 110A may be comprised of nitrogen-enriched silicon carbide, which may also be provided with high compressive stress if a respective higher stress level is considered appropriate for the first transistor 150A.

Similarly, a second dielectric layer 110B, such as a second contact etch stop layer, may be formed above the second transistor 150B and may have, in one illustrative embodiment, a high intrinsic stress appropriate for enhancing the performance of the second transistor 150B. For instance, when the transistor 150B represents an N-channel transistor, the second dielectric layer 110B may be provided with high tensile stress in the range of 1 GPa or significantly higher. For example, the second layer 110B may be comprised of silicon nitride which may be deposited so as to exhibit the desired high tensile stress.

The semiconductor device 100 as shown in FIG. 1a may be formed according to the following processes. After providing the substrate 101 having formed thereon the semiconductor layer 102, respective isolation structures may be formed in order to define the active regions of the transistors 150A, 150B. Thereafter, an appropriate vertical dopant profile may be established, for instance, as required for a P-channel transistor and an N-channel transistor. Thereafter, the gate electrodes 106 and the gate insulation layers 105 may be formed on the basis of sophisticated oxidation and/or deposition techniques followed by advanced photolithography processes and highly sophisticated etch techniques for patterning the gate electrodes 106 and the gate insulation layer 105. Next, the spacer structure 107 may be formed with dimensions as required for profiling the lateral dopant concentration for the drain and source regions 103 of the transistors 150A, 150B on the basis of sophisticated ion implantation techniques and/or diffusion processes, epitaxial growth techniques and the like. After having incorporated the required doping concentrations, appropriate anneal processes may be performed at any appropriate manufacturing stage to activate the dopants and re-crystallize implantation-induced lattice damage. Moreover, respective metal silicide processes may be performed if a respective reduction of the resistance of the contact portions of the transistors 150A, 150B is required. Thereafter, the etch stop layers 110A, 110B may be formed on the basis of appropriate deposition techniques, such as PECVD, wherein, in some illustrative embodiments, the first layer 110A may be provided in the form of a silicon nitride layer, a nitrogen-enriched silicon carbide layer and the like, having a compressive stress of desired amount when the first transistor 150A represents a P-channel transistor. The second etch stop layer 110B may be deposited on the basis of PECVD, for instance, in the form of a silicon nitride material having a high intrinsic tensile stress. A respective process regime for providing the layers 110A, 110B with a different type or amount of intrinsic stress, a different material composition and the like may involve lithography processes and etch techniques, depending on the characteristics of the layers 110A, 10B. For instance, one or more etch stop layers (not shown) or liner materials may be used to remove respective unwanted portions of the layers 110A, 110B so as to locally form the layers 110A, 110B having the desired characteristics. In some illustrative embodiments, a corresponding process strategy may be significantly enhanced by reducing the number of process steps, as will be described later on with reference to FIG. 1f. During the deposition of the first and second layers 110A, 110B, the layer thickness and the deposition parameters may be adjusted with respect to the pattern density and the critical dimensions of the device 100 to obtain the required etch stop capabilities of the layer 110A, 110B and also to comply with respect process constraints, for instance, in view of patterning the layers 110A, 110B and the like.

FIG. 1b schematically illustrates the semiconductor device 100 in a further advanced manufacturing stage. Here, the device 100 may comprise an interlayer dielectric material 111 having a high intrinsic stress level that is formed at least above one of the transistors 150A, 150B. In one illustrative embodiment, the interlayer dielectric material 111 may be provided in the form of a silicon dioxide based material having a high compressive stress so as to enhance the strain in one of the transistors 150A, 150B. For instance, it may be assumed that the first transistor 150A represents a P-channel transistor. In this case, the high compressive stress, which may be approximately 400 Mega Pascal and even higher, may substantially affect the channel region 104 of the first transistor 150A, contrary to conventional strategies in which, typically, stress levels on the order of 100 Mega Pascal are used in interlayer dielectric layers that do not substantially affect the corresponding strain level in the channel region 104.

In some illustrative embodiments, the first etch stop layer 110A may also be provided with a compressive stress, thereby further enhancing the overall strain created in the channel region 104 of the transistor 150A since the entire dielectric material 111 provided above the first transistor 150A may thus take part in the generation of a respective strain therein. In short, the compressive stress in the dielectric layer 111 may act to reinforce the compressive stress created by the layer 110A. In other embodiments, the stress level in the first layer 110A may be significantly lower compared to the stress level in the interlayer dielectric material 111 so that the corresponding strain-inducing mechanism is substantially provided by the material 111.

In the embodiment shown, the material 111 having the high internal compressive stress level may also be formed above the second etch stop layer 110B, which may have a high tensile stress, thereby efficiently shielding or reducing the effect of the compressive stress of the layer 111 from the second transistor 150B. Consequently, a significant enhancement of transistor performance may be obtained for the transistor 150A while not unduly negatively affecting the performance of the transistor 150B. Enhanced process uniformity may be achieved during the further processing of the device 100 irrespective of the device configuration of the device 100, such as reduced pitch of neighboring transistors receiving the same etch stop layer and the like, since less stringent constraints during the deposition of the layers 110A, 110B with respect to conformality, intrinsic stress and layer thickness have to be met. Contrary to this, in conventional strategies, a high stress level and a high layer thickness may be required for the corresponding contact etch stop layers, since channel strain may be induced by these layers only. Thus, these requirements in conventional strategies may be in conflict with respect gap fill requirements at reduced device dimensions due to limited conformality capability of the deposition process.

In other illustrative embodiments, the effect of the highly stressed interlayer dielectric material 111 may be reduced above the second transistor 150B by a selective ion bombardment of a portion of the dielectric material 111 on the basis of a heavy inert ionic species, such as xenon and the like, thereby relaxing the internal stress above the second transistor 150B. Such a treatment may be performed before or after the formation of respective contact openings (not shown in FIG. 1b). In an example disclosed herein, the further processing may be performed on the basis of the device as shown in FIG. 1b and as will be described later on with reference to FIG. 1c so as to form respective contact openings 112. These openings 112 may then be refilled during a corresponding lithography process for forming a respective implantation mask in order to cover the first transistor 150A and expose the second transistor 150B to the ion bombardment, which may finally result in a corresponding stress relaxation substantially without affecting the second etch stop layer 110B.

Other appropriate techniques for reducing the effect of the highly stressed interlayer dielectric material 111 on the second transistor 150B while maintaining a high degree of similarity in the further processing will be described later on with reference to FIGS. 1d-1f.

The highly stressed interlayer dielectric material 111 may be formed on the basis of PECVD techniques, as previously described, wherein respective process parameters, such as ion bombardment, i.e., a bias power during the process, the flow rates of precursor materials such as silane, TEOS and carrier gases, such as oxygen and the like, pressure, temperature and the like, may be adjusted in order to obtain the desired amount of intrinsic stress in desired portions of the dielectric material 111. Appropriate recipes may be established on the basis of respective test procedures.

FIG. 1c schematically illustrates the semiconductor device 100 in a further advanced manufacturing stage. Here, the surface topography of the interlayer dielectric material 111 may be planarized in order to provide an appropriate surface for performing a subsequent lithography process for forming an appropriate resist mask required for patterning contact openings 112. The planarization of the material 111 may be accomplished on the basis of CMP, wherein respective well-established recipes may be readily adapted to the mechanical and chemical characteristics of the material 111 which may be different compared to conventional silicon dioxide based dielectrics having a significantly lower intrinsic stress level. Similarly, the corresponding well-established anisotropic etch recipes for forming the contact openings 112 may be readily adapted to the characteristics of the material 111, for instance, by selecting appropriate flow rates and supply rates of reactive components and the like. In some illustrative embodiments, the interlayer dielectric material 111 having the high intrinsic stress may be similar in composition compared to conventional silicon dioxide based dielectric materials and hence a corresponding adaptation may be readily established based on conventional recipes. During the corresponding anisotropic process, the first and second layers 110A, 110B may act as etch stops, wherein enhanced process uniformity achieved during the formation of the layers 110A, 110B by less strict constraints with respect to intrinsic stress levels, as previously explained, may also result in appropriate etch stop capabilities during the formation of the contact openings 112. Thereafter, the etch stop layers 110A, 110B may be opened on the basis of respective etch recipes wherein, for instance, well-established techniques may be used when the layers 110A, 110B may be comprised of silicon nitride, nitrogen-enriched silicon carbide and the like. Thereafter, the further processing may be continued on the basis of conventional techniques, that is, the respective openings 112, which may now extend to respective contact portions of the transistors 150A, 150B may be filled with an appropriate conductive material, such as tungsten, copper and the like, and thereafter any further metallization levels may be formed above the interlayer dielectric material 111.

As a consequence, the strain-inducing mechanism, at least for one of the transistors 150A, 150B, may be significantly enhanced by efficiently increasing the amount of stressed dielectric material 111 acting on the respective transistor, wherein a high degree of compatibility with conventional strategies may be maintained with respect to formation of the contact openings 112. For instance, silicon dioxide based materials with high intrinsic stress may be used in combination with appropriately designed etch stop layers in order to efficiently adjust the strain level in at least one transistor, such as the transistor 150A. In other illustrative embodiments, the enhanced strain-inducing mechanism may be performed on the basis of other material compositions in order to provide enhanced highly stressed material above one or more types of transistors while nevertheless provide an efficient patterning regime for forming the respective contact openings 112.

For example, the etch stop layers 110A, 110B may be comprised of other materials, such as silicon dioxide, having an appropriate intrinsic stress, while the interlayer dielectric material 111 may be provided in the form of other appropriate materials, such as silicon nitride, nitrogen-enriched silicon carbide and the like. In this case, the respective interlayer dielectric material 111 may be deposited with high intrinsic stress since a corresponding highly conformal deposition behavior may not be required in the interlayer level as the resulting surface topography may then be adjusted by chemical mechanical polishing and the like. The respective etch process for forming the contact openings 112 may then be performed on the basis of highly selective anisotropic etch techniques, wherein the silicon dioxide based etch stop layers 110A, 110B provide high etch selectivity and, thus, stop characteristics. For example, similar etch techniques may be employed as are frequently used in sophisticated spacer techniques, such as processes for forming the spacer structure 107 when comprised of silicon dioxide liners and silicon nitride spacer elements.

FIG. 1d schematically illustrates the semiconductor device 100 according to further illustrative embodiments in which a silicon dioxide based dielectric buffer layer 113 may be provided above the second transistor 150B so as to reduce the effect of the highly stressed dielectric material 111 (FIGS. 1b-1c) in the second transistor 150B. As shown, the buffer layer 113, which may have a similar material composition compared to the dielectric material 111 still to be formed, may be provided, which, in one illustrative embodiment, may represent a silicon dioxide based material. The buffer layer 113 may have a significantly lower intrinsic stress level compared to the material 111 or may have even a different type of intrinsic stress. For example, the buffer layer 113 may be formed on the basis of a plasma enhanced deposition technique as previously described wherein the corresponding process parameters may be selected so as to provide a significantly reduced intrinsic stress, such as approximately 100 Mega Pascal or less, as is used in conventional strategies. In some illustrative embodiments, even a moderately high tensile stress may be achieved on the basis of plasma enhanced deposition techniques. In other illustrative embodiments, the buffer layer 113 may be formed on the basis of a SACVD process on the basis of TEOS, as previously explained, thereby obtaining a moderately high tensile stress during the deposition. The material of the buffer layer 113 may be deposited during the SACVD process so as to exhibit a tensile stress, thereby enhancing the respective tensile stress in the etch stop layer 110B. The SACVD process may be performed at high pressures and at a temperature of approximately 400-600° C. which may still be compatible within a thermal budget of the device 100 in this manufacturing stage. Furthermore, the buffer layer 113 may be deposited as a substantially conformal layer irrespective of the complex surface topography which may be encountered in sophisticated semiconductor devices, while, in other cases, the respective process parameters, such as pressure and temperature, may be selected so as to obtain a substantially flow-like deposition behavior, thereby equalizing to a certain degree the surface topography obtained after the formation of the etch stop layers 110A, 110B. In this case, a subsequent lithography process for forming a resist mask 114 may be enhanced, due to the reduced surface topography. Next, an exposed portion of the buffer layer 113 formed above the first transistor 150A may be removed, for instance on the basis of well-established etch recipes, wherein the etch stop layer 110A may act as an efficient etch stop. It should be appreciated that a certain degree of damage and, thus, material removal of the etch stop layer 110A may not substantially negatively affect the overall strain-inducing mechanism since the desired strain level may be appropriately adjusted by the highly stressed interlayer dielectric material 111 to be formed.

FIG. 1e schematically illustrates the semiconductor device 100 in a further advanced manufacturing stage wherein the interlayer dielectric material 111 is formed on the first etch stop layer 110A and the remaining portion of the buffer layer 113. With respect to the characteristics of the interlayer dielectric material 111 and any processes for forming the same, the same criteria apply as previously explained. It should be appreciated that a corresponding increased surface topography of the device 100 of FIG. 1e may be readily planarized on the basis of CMP and the like as previously explained. Consequently, the further processing of the device may be continued as is described above with reference to FIG. 1c, wherein the high degree of similarity in material composition of the buffer layer 113 and the interlayer dielectric material 111 may provide a substantially uniform etch process when forming the respective contact openings in the interlayer dielectric material 111 and the buffer layer 113.

FIG. 1f schematically illustrates the semiconductor device 100 according to a further illustrative embodiment in which the dielectric buffer layer 113 may be formed with a moderately high intrinsic stress, wherein portions of the buffer layer 113 may then be selectively relaxed on the basis of the resist mask 114 and an ion implantation process 115. In the embodiment shown, the buffer layer 113 may be provided with high tensile stress, for instance, using a thermal CVD process as previously described, in order to enhance the performance of transistor 150B when representing an N-channel transistor. In this case, the ion implantation 115 may be performed on the basis of a silicon species, thereby relaxing the tensile stress in the exposed portion of the layer 113 while also providing additional silicon material which may then be available for a further thermal treatment in the form of an oxidation process. For example, after the ion implantation process 115 incorporating additional silicon species while relaxing the tensile stress, a subsequent heat treatment, for instance, on the basis of an oxidizing ambient at elevated temperatures in the range of 400-600° C. may result in increased compressive stress above the transistor 150A thereby forming a compressive buffer layer 113a. On the other hand, the tensile stress in the portion 113b may be even further enhanced by removing any traces of moisture or water which may otherwise lead to a reduction of the tensile stress, as previously explained. Thereafter, the interlayer dielectric material 111 may be formed on the portions 113a, 113b on the basis of processes as previously explained, thereby further enhancing the overall compressive stress in the first transistor 150A while the portion 113b may efficiently compensate for or over compensate for the effect of the interlayer dielectric material 111.

In still other illustrative embodiments, the first transistor 150A in FIG. 1f may represent an N-channel transistor while the second transistor 150B may represent a P-channel transistor. In this case, the buffer layer 113 may be formed with high intrinsic compressive stress on the basis of PECVD techniques, as previously described, wherein the implantation 115 may result in a corresponding relaxation of the high intrinsic stress above the first transistor 150A. Consequently, after the deposition of the highly stressed interlayer dielectric material 111 above the buffer layer 113, a further stress enhancement may be achieved in the transistor 150B while a significantly reduced effect on the first transistor 150A may result due to the presence of the substantially “neutral” buffer layer 113a. Since the buffer layer 113 may be formed with an appropriate thickness, for instance, in the range of several tenths of nanometers, an appropriate effect with respect to the stress conditions of the lower lying transistor may be achieved while nevertheless not unduly affecting the overall characteristics during the subsequent anisotropic etch process.

FIG. 1g schematically illustrates the semiconductor device 100 according to a further illustrative embodiment in which a simplified process regime is used for forming the etch stop layers 110A, 10B with a different amount of intrinsic stress. As shown, the device 100 may have formed thereon the layers 110A, 110B which may be provided as a continuous layer having a high intrinsic stress as is appropriate for the second transistor 150B. For instance, the layer 110B may be provided with a high tensile stress when the interlayer dielectric material 111 is to be provided with high intrinsic compressive stress. In this case, a sophisticated and complex stress engineering technique for the layers 110A, 110B may not be required since the stress level in the first transistor 150A may be substantially adjusted on the basis of the interlayer dielectric material 111 still to be formed. Hence, the corresponding material of the layers 110A and 110B may be formed in a common manufacturing process and may, in particular, be substantially directly formed on the transistors 150A, 150B, thereby enhancing the stress transfer efficiency in the second transistor 150B. Thereafter, the resist mask 117 may be formed on the basis of well-established lithograph techniques, thereby exposing the first transistor 150A. In a subsequent implantation process 116, the high intrinsic stress may be relaxed, for instance, on the basis of an inert species such as xenon and the like thereby substantially “neutralizing” the intrinsic stress so as to form the first etch stop layer 110A. Thereafter, the further processing may be continued by depositing the highly stressed interlayer dielectric material 111, wherein an appropriate dielectric buffer layer 113 may also be provided as previously explained in order to reduce the effect of the highly stressed material 111 on the second transistor 150B.

As a result, the embodiments disclosed herein may provide for a significant transistor enhancement, at least for one transistor element, by extending the stress engineering into the interlayer dielectric material 111, thereby providing the potential for further device scaling since respective constraints, imposed by sophisticated surface topography of highly scaled transistor devices, associated with the deposition of conventional highly stressed silicon nitride contact etch stop layers of increased thickness may be overcome. In some illustrative embodiments, the highly compressive silicon dioxide based material may be deposited above the respective contact etch stop layers, thereby significantly increasing the performance of P-channel transistors. For instance, using a 400 Mega Pascal compressive interlayer dielectric material formed on the basis of TEOS may increase drive current of P-channel transistors by about 2% with respect to an identical device having a conventional silicon dioxide interlayer dielectric material with a conventional stress level of approximately 100 MPa. Furthermore, in this illustrative example, the respective highly compressively stressed interlayer dielectric material is directly formed on the respective contact etch stop layers, that is, without an additional buffer layer as previously described, thereby resulting in a performance gradation of the N-channel transistor, which is however less than 1%. For such a device configuration, in total, the device performance measured on the basis of the frequency of a ring oscillator is increased by 1% without additional process complexity, while also a high degree of compatibility to conventional strategies for forming contact openings may be maintained. In still other illustrative embodiments, the concept of extending the stress engineering into the level of the interlayer dielectric material may result in higher performance of both types of transistors when respective buffer materials with appropriately adjusted intrinsic stress levels may be incorporated into the interlayer dielectric material.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a first etch stop layer above a P-channel transistor; and
forming an interlayer dielectric material above said first etch stop layer, said interlayer dielectric material comprising at least a layer portion having a compressive stress of approximately 400 MPa (Mega Pascal) or higher.

2. The method of claim 1, further comprising forming a contact opening in said interlayer dielectric material using said first etch stop layer as an etch stop.

3. The method of claim 1, wherein said interlayer dielectric material is comprised of silicon dioxide.

4. The method of claim 1, wherein said first etch stop layer has compressive stress.

5. The method of claim 3, wherein said interlayer dielectric material is formed by a plasma enhanced chemical vapor deposition process on the basis of one of TEOS and silane.

6. The method of claim 1, wherein said first etch stop layer comprises silicon and nitrogen.

7. The method of claim 6, wherein said first etch stop layer further comprises carbon.

8. The method of claim 1, further comprising forming a second etch stop layer above an N-channel transistor, said second etch stop layer having intrinsic tensile stress, wherein said interlayer dielectric material is formed above said first and second etch stop layers.

9. The method of claim 8, further comprising forming a dielectric buffer material above said second etch stop layer prior to forming said interlayer dielectric material above said first and second etch stop layers, said dielectric buffer material reducing a stress effect of said interlayer dielectric material on said N-channel transistor.

10. The method of claim 9, wherein said dielectric buffer material is formed so as to have tensile stress.

11. The method of claim 10, wherein said dielectric buffer material is formed on the basis of a thermal chemical vapor deposition process using TEOS.

12. A method, comprising:
forming a first etch stop layer above a first transistor;
forming a second etch stop layer above a second transistor, said first and second etch stop layers having at least one of a different amount and type of intrinsic stress; and
forming an interlayer dielectric material above said first and second etch stop layers, said interlayer dielectric material comprising a portion located above said first transistor and having an intrinsic stress level selected to adjust a strain level in a channel region of said first transistor.

13. The method of claim 12, wherein said intrinsic stress level is approximately 400 Mega Pascal or higher.

14. The method of claim 13, wherein said second etch stop layer is formed with an intrinsic tensile stress and said interlayer dielectric material is formed at least above said first transistor with compressive stress.

15. The method of claim 14, wherein forming said first and second etch stop layers comprises forming a dielectric material with intrinsic tensile stress above said first and second transistors and selectively reducing said tensile stress above said first transistor.

16. The method of claim 12, wherein forming said interlayer dielectric material comprises selectively forming a dielectric buffer layer above said second transistor, and forming a further dielectric layer having said intrinsic stress level above said dielectric buffer layer, said dielectric buffer layer differing in at least one of type and amount of intrinsic stress from said further dielectric layer.

17. The method of claim 16, wherein selectively forming said dielectric buffer layer comprises forming said dielectric buffer layer above said first and second transistors and removing a portion of said dielectric buffer layer from above said first transistor.

18. The method of claim 17, wherein selectively forming said dielectric buffer layer comprises forming said dielectric buffer layer above said first and second transistors with tensile stress and modifying a portion of said dielectric buffer layer located above said first transistor so as to reduce said tensile stress.

19. The method of claim 12, wherein said interlayer dielectric material is formed on the basis of one of TEOS and silane.

20. A semiconductor device, comprising:
a first transistor;
a first etch stop layer formed above said first transistor; and
a first interlayer dielectric material formed on said first etch stop layer, said interlayer dielectric material having an intrinsic stress level above said first transistor of approximately 400 Mega Pascal or higher.

21. The semiconductor device of claim 20, further comprising a second transistor and a second etch stop layer formed above said second transistor, said second etch stop layer having an intrinsic stress other than an intrinsic stress of said first interlayer dielectric material, wherein said first interlayer dielectric material is formed above said second etch stop layer.

22. The semiconductor device of claim 21, further comprising a dielectric buffer layer formed on said second etch stop layer, said dielectric buffer layer differing from said first interlayer dielectric material in at least one of type and amount of intrinsic stress.
